(19) United States
(12) Patent Application Publication
(10) Pub. No.: US 2012/0223308 A1
(43) Pub. Date: Sep. 6, 2012

(54) THIN-FILM TRANSISTOR, PROCESS FOR PRODUCTION OF SAME, AND DISPLAY DEVICE EQUIPPED WITH SAME

(75) Inventors: Tohru Okabe, Osaka-shi (JP); Yoshimasa Chikama, Osaka-shi (JP)

(73) Assignee: SHARP KABUSHIKI KAISHA, Osaka-shi, Osaka (JP)

(21) Appl. No.: 13/500,100

(22) PCT Filed: Jun. 17, 2010
(86) PCT No.: PCT/JP2010/060309

§ 371 Date: Apr. 18, 2012

(30) Foreign Application Priority Data
Oct. 16, 2009 (JP) 2009-239716

(51) Int. Cl. H01L 29/786; H01L 21/461

(52) U.S. Cl. 257/43; 438/104; 257/E29.296; 257/E21.483

(57) ABSTRACT

The present invention provides a thin-film transistor capable of high-speed operation, a process for producing the same, and a display device including the same. The thin-film transistor of the present invention includes, on a substrate, in the order of: a gate electrode; a gate insulating film; an oxide semiconductor film; and a protective insulating film, the protective insulating film having a planar shape that is completely or substantially the same as the planar shape of the gate electrode.

### TECHNICAL FIELD

The present invention relates to a thin-film transistor, a process for producing the same, and a display device including the same. More specifically, the present invention relates to a thin-film transistor including an oxide semiconductor film, a process for producing the same, and a display device including the same.

### BACKGROUND ART

Known thin-film transistors (TFTs) include bottom-gate TFTs in which the gate electrodes are first formed. Today, bottom-gate TFTs including amorphous silicon as the semiconductor layers are generally used as the switching elements of large flat panel displays (FPDs). Also, TFTs including etching stopper layers and channel etching-type TFTs are mass-produced.

In recent years, development of TFTs including oxide semiconductors as semiconductor layers has been actively carried out. For example, Patent Document 1 discloses a technique for optimizing the carrier density and film thickness of the oxide semiconductor layer.

Patent Document 1: JP 2008-218495 A

### SUMMARY OF THE INVENTION

Those FPDs are desired to have a larger size, a higher resolution, and a higher frame rate in the future, and as a result, TFTs are desired to have a higher mobility and a lower capacitance.

The bottom-gate TFTs including oxide semiconductors as the semiconductor layers can be made to have a mobility that is substantially 20 times the mobility of TFTs including amorphous silicon as the semiconductor layers (hereinafter, such TFTs including amorphous silicon are also referred to as “a-Si TFTs”). Therefore, high-quality

FPDs which cannot be produced with the conventional a-Si TFTs can be produced.

However, since the mobility of the oxide semiconductor is sufficiently high, the parasitic capacitance of the TFT itself and the parasitic capacitance at the crossing portions of the gate wirings and the source wirings, which have not been questioned for the conventional a-Si TFTs, cannot be ignored because the parasitic capacitance sometimes delays the signals and disables the TFT at the time of driving a panel that requires a high mobility.

More specifically, as illustrated in FIG. 17, the conventional channel-etching bottom-gate TFT structures include a gate electrode 1011, an insulating film 1013, a semiconductor film 1014, source/drain electrodes 1015, and a passivation film 1019 which are formed in this order. The source/drain electrodes 1015 are patterned to greatly overlap the gate electrode 1011 from the ends of the gate electrode 1011. Therefore, when the TFT is operated, the parasitic capacitance of the TFT itself will occur between the gate electrode 1011 and the semiconductor film 1014. When the TFT is not operated, parasitic capacitance 1030 of the TFT itself will occur at portions where the gate electrode 1011 and the source/drain electrodes 1015 overlap each other. As illustrated in FIG. 18, at a portion other than the TFTs where a gate wiring 1012 connected to the gate electrode 1011 overlaps a source wiring 1018 connected to the source electrode of the source/drain electrodes 1015, the parasitic capacitance 1030 will occur between the gate wiring 1012 and the source wiring 1018. Therefore, even if an oxide semiconductor is used as the material of the semiconductor film 1014, highly efficient large FPDs sometimes cannot be operated normally.

The present invention has been made in view of the above state of the art, and aims to provide a thin-film transistor capable of high-speed operation, a process for producing the same, and a display device including the same.

The present inventors have made various studies on thin-film transistors capable of high-speed operation, and have noted the technique for forming a protective insulating film as an etching stopper layer. As a result, allowing the protective insulating film to have a planar shape that is completely or substantially the same as the planar shape of the gate electrode has been found to enable to substantially eliminate or greatly reduce the parasitic capacitance between a gate electrode and the source/drain electrode. The finding achieves the above aim admirably, which has led to the present invention.

That is, the present invention relates to a bottom-gate thin-film transistor, including, on a substrate, in the order of: a gate electrode; a gate insulating film; an oxide semiconductor film; and a protective insulating film, the protective insulating film having a planar shape that is completely or substantially the same as the planar shape of the gate electrode.

Thereby, the overlapping portion of the gate electrode and the source/drain electrode can be made small, or the distance between the gate electrode and the source/drain electrode can be increased. It is therefore possible to substantially eliminate or greatly reduce the parasitic capacitance. Further, the mobility can be improved. The TFT therefore can be operated at a high speed.

Here, “the protective insulating film has a planar shape that is substantially the same as the planar shape of the gate electrode” may mean that the shapes are the same to the extent achieved by patterning to form the protective insulating film by the technique of exposure using the gate electrode as a mask.

As long as the above components are essentially included, the structure of the thin-film transistor of the present invention is not particularly limited by other components.

The preferred embodiments of the thin-film transistor of the present invention are described in detail below. The various embodiments shown below may be appropriately combined.

It is preferable that the thin-film transistor further comprises a source/drain electrode connected to a channel formed in the oxide semiconductor film, wherein the source/drain electrode and the oxide semiconductor film are formed from the same semiconductor layer, and the source/drain electrode is formed by reducing a part of the semiconductor layer. In this case, an end of the source/drain electrode and an end of the gate electrode can be completely or substantially aligned, which enables to completely or substantially eliminate the parasitic capacitance.

The process for reducing a part of the semiconductor layer is not particularly limited, and a process using hydrogen plasma is suitable. Since hydrogen plasma can be easily generated by introducing hydrogen gas into a plasma CVD device or a dry etching device and is a gas having the smallest atomic weight, use of hydrogen plasma enables to minimize the damage to portions that are exposed to plasma.

The thin-film transistor may further comprise a gate wiring connected to the gate electrode, wherein the protective insulating film preferably extends over the gate wiring, and the protective insulating film preferably has a planar shape that is completely or substantially the same as the planar shape of the gate wiring. Thereby, the parasitic capacitance at the crossing portion of the source wiring connected to the source/drain electrode and the gate wiring can be reduced. Since the protective insulating films can be simultaneously formed over the gate electrode and the gate wiring by the technique of exposure from the backside of the substrate, the steps can be simplified.

Here, “the protective insulating film has a planar shape that is substantially the same as the planar shape of the gate wiring” may mean that the shapes are the same to the extent achieved by patterning to form the protective insulating film by the technique of exposure using the gate wiring as a mask.

The protective insulating film preferably contains SiO₂ (silicon dioxide). Thereby, the protective insulating film can show better properties than the insulating films containing hydrogen (e.g., SiNx film). This is because an oxide semiconductor film is easily affected by hydrogen. Further, SiO₂ has a lower dielectric constant than SiNx, and thus leaving a protective insulating film containing SiO₂ at the crossing portions of the gate wirings and the source wirings can greatly decrease the parasitic capacitance at the crossing portions. In addition, it is possible to prevent hydrogen from entering the channel and achieve good properties even when the source/drain electrode is formed using hydrogen plasma.

The oxide semiconductor film preferably contains at least one element selected from the group consisting of indium, gallium, zinc, aluminum, and silicon, and more preferably contains indium, gallium, and zinc. In this case, an oxide semiconductor film can be formed at comparatively low temperatures of room temperature to 150° C., and thus TFTs can be formed on a flexible substrate formed using a film as a base material. Since the oxide semiconductor film can be formed by sputtering, the TFTs can be produced through simple steps. Also, the oxide semiconductor films are more transparent than semiconductor films formed from amorphous silicon, which allows light absorption by the semiconductor film to be very small when the exposure is performed from the backside of the substrate. Therefore, a cheap long-wavelength exposure machine can be used, and the exposure amount and the exposure time can be reduced. The exposure from the backside of the substrate is difficult with a semiconductor film formed from amorphous silicon if the film thickness is not smaller than 50 nm, but the exposure from the backside of the substrate is possible with an oxide semiconductor film even if the film thickness is not smaller than 50 nm. Therefore, the film thickness can be made larger, so that the parasitic capacitance of TFTs and the parasitic capacitance at the crossing portions of the gate wirings and the source wirings can be reduced greatly.

The present invention also relates to a process for producing the thin-film transistor of the present invention, and the process comprises exposing a resist layer formed on the insulating layer used to form the protective insulating film, from the substrate side. Thereby, the thin-film transistor of the present invention can be produced easily.

As long as the above steps are essentially included, the process for producing the thin-film transistor of the present invention is not particularly limited by other steps.

The present invention also relates to a display device including the thin-film transistor of the present invention. The display device of the present invention, including thin-film transistors capable of high-speed operation, can be made to have a larger size, a higher resolution, and a higher frame rate.

As long as the above components are essentially formed, the structure of the display device of the present invention is not particularly limited by other components.

It is preferable that the source/drain electrode functions as a source electrode, the thin-film transistor further comprises a gate wiring connected to the gate electrode and a source wiring connected to the source electrode, the protective insulating film extends over the gate wiring, and at a crossing portion of the gate wiring and the source wiring, at least one of the protective insulating film and the oxide semiconductor film has a planar shape that is completely or substantially the same as the planar shape of the gate wiring. Here, more preferably, both the protective insulating film and the oxide semiconductor film have a planar shape that is completely or substantially the same as the planar shape of the gate wiring. In this case, the parasitic capacitance at a crossing portion of the source wiring and the gate wiring can be reduced. Since a protective insulating film and/or an oxide semiconductor film can be simultaneously formed over the gate electrode and the gate wiring by the technique of exposure from the backside of the substrate, the steps can be simplified. As above, the thin-film transistor may further include a gate wiring connected to the gate electrode and a source wiring connected to the source/drain electrode functioning as the source electrode.

Here, “the protective insulating film has a planar shape that is substantially the same as the planar shape of the gate wiring” may mean that the shapes are the same to the extent achieved by patterning to form the protective insulating film by the technique of exposure using the gate wiring as a mask.

Here, “the oxide semiconductor film has a planar shape that is substantially the same as the planar shape of the gate wiring” may mean that the shapes are the same to the extent achieved by patterning to form the protective insulating film by the technique of exposure using the gate wiring as a mask, or by further patterning to form the oxide semiconductor film using the mask (resist) used in patterning to form the protective insulting film.

The thin-film transistor of the present invention is capable of high-speed operation.

The process for producing a thin-film transistor according to the present invention enables to easily produce the thin-film transistor of the present invention.

The display device of the present invention can be made to have a larger size, a higher resolution, and a higher frame rate.

### BRIEF DESCRIPTION OF DRAWINGS

FIG. 1 is a schematic cross-sectional view illustrating the structure of a thin-film transistor according to a first embodiment.

FIG. 2 is a schematic cross-sectional view illustrating the structure of a flat panel display according to the first embodiment.

FIG. 3 is a schematic cross-sectional view illustrating the structure of the thin-film transistor according to the first embodiment in a production step.

FIG. 4 is a schematic cross-sectional view illustrating the structure of the thin-film transistor according to the first embodiment in a production step.

FIG. 5 is a schematic cross-sectional view illustrating the structure of the thin-film transistor according to the first embodiment in a production step.

FIG. 6 is a schematic cross-sectional view illustrating the structure of the thin-film transistor according to the first embodiment in a production step.

FIG. 7 is a schematic cross-sectional view illustrating the structure of the thin-film transistor according to the first embodiment in a production step.

FIG. 8 is a schematic cross-sectional view illustrating the structure of the thin-film transistor according to the first embodiment in a production step.

FIG. 9 is a schematic cross-sectional view illustrating the structure of the thin-film transistor according to the first embodiment in a production step.

FIG. 10 is a schematic cross-sectional view illustrating the structure of a thin-film transistor according to a second embodiment.

FIG. 11 is a schematic cross-sectional view illustrating the structure of the thin-film transistor according to the second embodiment in a production step.

FIG. 12 is a schematic cross-sectional view illustrating the structure of the thin-film transistor according to the second embodiment in a production step.

FIG. 13 is a schematic cross-sectional view illustrating the structure of a thin-film transistor according to a third embodiment.

FIG. 14 is a schematic cross-sectional view illustrating the structure of the thin-film transistor according to the third embodiment in a production step.

FIG. 15 is a schematic cross-sectional view illustrating the structure of the thin-film transistor according to the third embodiment in a production step.

FIG. 16 is a schematic cross-sectional view illustrating the structure of the thin-film transistor according to the third embodiment in a production step.

FIG. 17 is a schematic cross-sectional view illustrating the structure of a conventional thin-film transistor.

FIG. 18 is a schematic cross-sectional view illustrating the structure of the conventional thin-film transistor.

### MODES FOR CARRYING OUT THE INVENTION

The present invention will be described in more detail referring to the drawings, based on the following embodiments which, however, are not intended to limit the scope of the present invention.

In the present description, the source/drain electrode is an electrode that functions as the source electrode or drain electrode of the TFT. That is, one TFT has two source/drain electrodes, one of which functions as a source electrode and the other of which functions as a drain electrode.

The source/drain wiring is a wiring that functions as a source wiring or drain wiring.

### First Embodiment

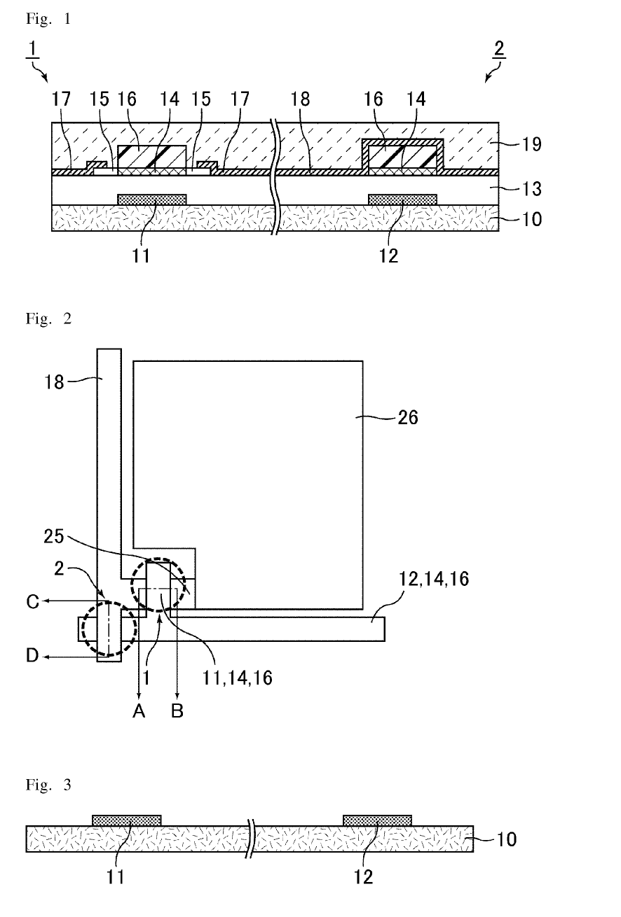

The thin-film transistor of the present embodiment is provided with a transistor portion 1 and a source-gate crossing portion 2 which are formed on a glass substrate 10 as illustrated in FIG. 1. The glass substrate 10 is a substrate for a flat panel display, which means that the thin-film transistor of the present embodiment is formed on a substrate for a flat panel display. As illustrated in FIG. 2, the transistor portion 1 drives the corresponding pixel of the flat panel display, and the source-gate crossing portion 2 is arranged in every pixel. Such a structure is concerned to increase the capacitance of the wirings at the source-gate crossing portions 2 as the display resolution increases and the number of display elements increases. The drawing (on the left) illustrating the transistor portion in FIG. 1 is a cross-sectional view taken along the A-B line in FIG. 2. The drawing (on the right) illustrating the source-gate crossing portion in FIG. 1 is a cross-sectional view taken along the C-D line in FIG. 2.

As illustrated in FIG. 2, the portion (a source wiring 18) which functions as a source of source/drain wirings 17 and a gate wiring 12 are arranged in a lattice shape, so that the source wiring 18 is arranged to cross the gate wiring 12 at the source-gate crossing portion 2. In this way, the source-gate crossing portion 2 has the source wiring 18 and the gate wiring 12 crossing each other. The transistor portion 1 is formed near the crossing portion of the wirings 18 and 12. Each pixel has a pixel electrode 26 that is connected to the transistor portion 1 via a portion (a drain wiring 25) which functions as a drain of the source/drain wirings 17.

As illustrated in FIG. 1, the glass substrate 10 has formed thereon a gate electrode 11 and the gate wiring 12 which are covered with an insulating layer 13. The insulating layer 13 has a semiconductor film 14 patterned to overlap the gate electrode 11 and the gate wiring 12. The semiconductor film 14 is formed from an IGZO film containing indium (In), gallium (Ga), zinc (Zn), and oxygen (0). At the transistor portion 1, the insulating layer 13 further has thereon source/drain electrodes 15 adjacent to the semiconductor film 14. The source/drain electrodes 15 are connected to the channel formed in the semiconductor film 14. On the semiconductor film 14, a protective insulating film 16 is formed at positions over the gate electrode 11 and the gate wire 12. The protective insulating film 16 functions as an etching stopper layer. The protective insulating film 16, the semiconductor film 14, and the gate electrode 11 or the gate wiring 12 have the completely or substantially the same planar shape. Over these components is formed a passivation film 19 that covers all of the components for protection.

Hereinafter, the production process of the present embodiment is described.

First, a copper (Cu) film which is a low resistance wiring is formed on the glass substrate 10 to a thickness of 200 to 400 nm. Then, the Cu film is patterned by photolithography such that the gate electrode 11 and the gate wiring 12 are integrally (continuously) formed as illustrated in FIG. 3. Since the wiring width of the gate electrode 11 is the channel length of the TFT, the wiring width was set to 5 to 15 μm. Here, a stacked wiring produced by sandwiching a low resistance wiring (e.g. aluminum (Al) film) by titanium (Ti) films may be used. Still, a copper (Cu) layer is preferred which can have a single layer or two-layer structure and can further reduce the wiring width. A flexible substrate formed using a film as a base material may be used instead of the glass substrate 10.

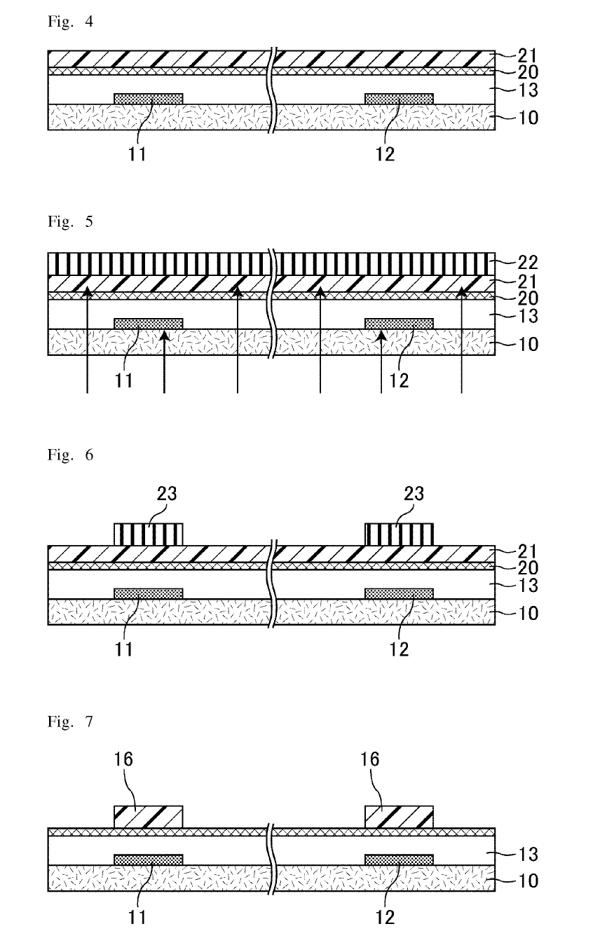

Next, as illustrated in FIG. 4, the insulating layer 13 is formed in such a manner to cover the glass substrate 10, the gate electrode 11, and the gate wire 12 by the CVD method. The insulating film 13 is more preferably an SiO₂ film than an SiNx film that is generally used for a-Si TFTs. This is because an SiO₂ film is compatible with an oxide semiconductor layer and has a lower dielectric constant than an SiNx film. Therefore, a stacked film of an SiNx film and an SiO₂ film or an SiON film may be used. The method for forming the insulating layer 13 may be sputtering, which enables to continuously form the insulating layer 13 and the oxide semiconductor layer to be formed subsequently. The film thickness of the insulating layer 13 is about 200 to 400 nm, and the portion of the insulating layer 13 above the gate electrode 11 functions as a gate insulating film.

Next, as illustrated in FIG. 4, an oxide semiconductor material containing In, Ga, Zn, and O is deposited on the insulating layer 13 by sputtering such that a semiconductor layer (oxide semiconductor layer) 20 is formed, and then an SiO₂ film 21 is formed on the semiconductor layer 20. The film thickness of the semiconductor layer 20 is about 50 to 200 nm (suitably 150 nm), and the film thickness of the SiO₂ film 21 is about 200 to 400 nm (suitably 300 nm).

Next, as illustrated in FIG. 5, a resist material is applied to the SiO₂ film 21 so that a resist layer 22 is formed. Then, the resist layer 22 is exposed from the backside of the glass substrate 10 in the direction indicated by the arrows (backside exposure). At this time, since the semiconductor layer 20 and the SiO₂ film 21 are formed from oxides and are transparent, the light can easily reach the resist layer 22 while the required exposure amount is maintained. The conditions of the backside exposure are shown below. That is, the entire surface of the glass substrate 10 was irradiated with an inexpensive low-pressure mercury lamp for an irradiation time of 2 to 5 seconds. The exposure amount was set to the same level as in the case of exposing the surface of an ordinary glass substrate 10. Specifically, the exposure amount was set to 20 to 50 mJ/cm². In the exposure, the gate electrode 11 and the gate wiring 12 function as masks. Then, the resist layer 22 is patterned through the development process, so that a resist 23 as illustrated in FIG. 6 is formed.

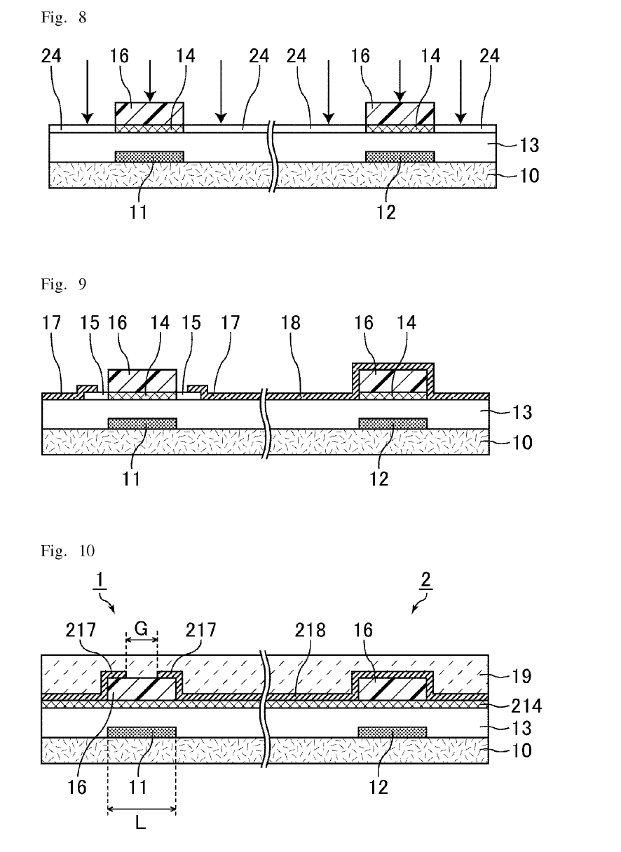

Next, as illustrated in FIG. 7, the dry etching process is performed by patterning the SiO₂ film 21 with the resist 23 as the mask, so that the protective insulating film 16 is formed. Then, the resist 23 is removed.

Next, as illustrated in FIG. 8, the glass substrate 10 is irradiated with hydrogen plasma from the upper side in the direction illustrated by the arrows. Thereby, the portions of the semiconductor film 14 where the protective insulating film 16 does not overlap are reduced to be conductive, and thereby these portions serve as a conducting film 24. In this way, an oxide semiconductor can be easily made into a conductor by eliminating oxygen through the reduction treatment such as hydrogen plasma treatment, unlike the other semiconductor materials. Meanwhile, the portions of the semiconductor film (oxide semiconductor film) 14 where the protective insulating film 16 overlaps are left as a semiconductor because hydrogen plasma is blocked by the protective insulating film 16 formed from the SiO₂ film 21.

Here, the hydrogen plasma treatment may be continuously performed after the dry etching step for forming the protective insulating film 16, and then the resist 23 may be removed.

Next, the source/drain electrodes 15 are formed by patterning the conductive film 24 by photolithography as illustrated in FIG. 9.

Next, a Ti film and a Cu film are formed to respective film thicknesses of 50 nm to 100 nm and 200 nm to 400 nm by sputtering. The Ti film is formed for improving adhesion to the oxide semiconductor layer and controlling diffusion of Cu. Then, the staked films are patterned by photolithography such that the source/drain wirings 17 including the source wiring 18 are formed as illustrated in FIG. 9.

Next, as illustrated in FIG. 1, the passivation film 19 is formed by the CVD method so as to cover all the components formed thus far. The passivation film 19 may be, for example, a highly moisture-resistant SiNx film having a film thickness of about 100 nm to 300 nm, or an SiON film having a film thickness of about 100 nm to 300 nm. The thin-film transistor of the present embodiment is completed as above.

Finally, an indium-tin oxide (ITO) film is formed to a film thickness of 50 to 150 nm by sputtering. Then, the ITO film is patterned by photolithography, so that the pixel electrode 26 is formed as illustrated in FIG. 2.

In the present embodiment, the protective insulating film 16 is formed by self alignment with the gate electrode 11 and the gate wiring 12 as masks. The source/drain electrodes 15 and the semiconductor film 14 are formed from the same semiconductor layer 20, and the source/drain electrodes 15 are formed by reducing a part of the semiconductor layer 20 with the protective insulating film 16 as a mask. In other words, the source/drain electrodes 15 are formed on the semiconductor layer 20 (the same layer as the semiconductor film 14) by self alignment with the protective insulating film 16 as a mask. Therefore, in a plan view of the substrate 10, the ends of the source/drain electrodes 15 and the ends of the gate electrode 11 can be aligned. That is, the overlapping of the source/drain electrodes 15 and the gate electrode 11 can be avoided, and therefore the parasitic capacitance can be eliminated.

The capacitance of the source-gate crossing portion 2 as well as the capacitance of the transistor portion 1 is loaded to the wiring 17, which may delay the signals. However, in the present embodiment, the capacitance of the source-gate crossing portion 2 can be greatly reduced because the insulating layer 13, the semiconductor film 14, and the protective insulating film 16 are stacked over the gate wiring 12.

As above, the TFT of the present embodiment is capable of high-speed operation.

### Second Embodiment

The structure of the thin-film transistor of the present embodiment is the same as that of the thin-film transistor of the first embodiment, except that the source/drain electrode formed by reducing a part of the oxide semiconductor layer is not provided.

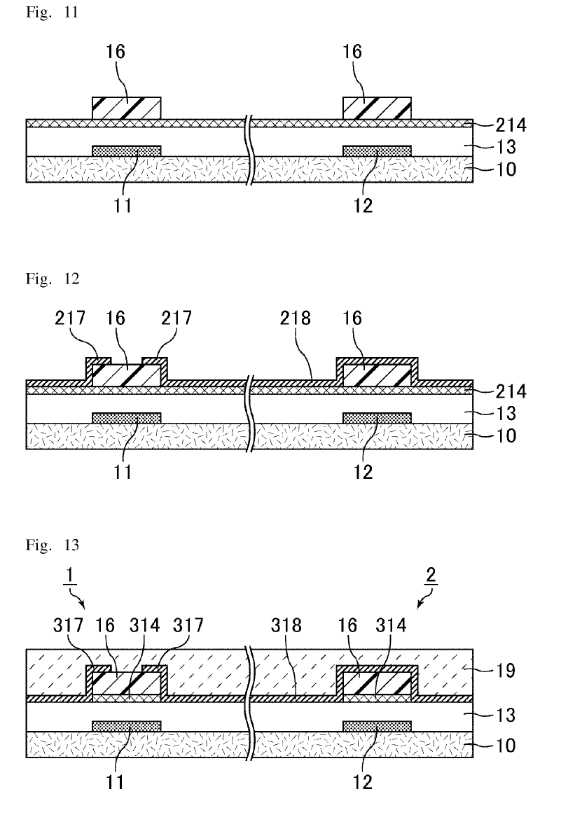

As illustrated in FIG. 10, the oxide semiconductor layer is left as is on the insulating layer 13, so that a semiconductor film 214 is arranged uniformly. The semiconductor film 214 has formed thereon the protective insulating film 16 at positions over the gate electrode 11 and the gate wiring 12. At the transistor portion 1, source/drain wirings 217 are formed in such a manner to partially overlap the protective insulating film 16. In the present embodiment, the source/drain wirings 217 also function as the source/drain electrodes.

In the present embodiment, the width L of the gate electrode 11 is 8 μm, and the width G of the space between the ends of the source/drain wirings 217 is 4 μm, in the channel length direction. Also, the length of the overlapping portion of the gate electrode 11 and the source/drain wiring 217 is 2 μm in the channel length direction. Thereby, generation of the parasitic capacitance which is generated between the source/drain electrode 217 on the protective insulating film 16 and the gate electrode 11 when the TFT is not operated can be prevented as much as possible. The capacitance can be further reduced by controlling the film thicknesses of the semiconductor film 214 and the protective insulating film 16 to the respective values of 50 to 200 nm and 200 to 400 nm.

Hereinafter, the production process of the present embodiment is described. Although almost all the steps are the same as those of the first embodiment, the hydrogen reduction treatment of the oxide semiconductor layer is not performed in the present embodiment. Use of a transparent oxide layer as the semiconductor layer enables to produce a semiconductor layer without patterning, and thus the production process can be shortened.

First, the steps are performed up to the step of forming the protective insulating film 16 by patterning through the same steps as in the first embodiment to form the structure illustrated in FIG. 11. In the present embodiment, the film thickness of the protective insulating film 16 is set to 200 to 400 nm.

Next, a Ti film and a Cu film are formed to the respective film thicknesses of 50 to 100 nm and 200 nm to 400 nm by sputtering. Then, the stacked films are patterned by photolithography, and the source/drain wirings 217 including a source wiring 218 are formed as illustrated in FIG. 12.

As illustrated in FIG. 10, the passivation film 19 is formed by a CVD method in such a manner to cover all the components formed thus far.

The present embodiment can decrease the number of steps compared to the first embodiment, and therefore the production cost can be reduced.

However, the source/drain wirings 217 remain in a small amount on the protective insulating film 16 at the transistor portion 1, which produces parasitic capacitance.

However, the capacitance includes the capacitance of the stacked product of the insulating layer 13, the semiconductor film 14, and the protective insulating film 16. The capacitance can be reduced by using a low dielectric constant material as the material of the protective insulating film 16 or by reducing the film thickness of the protective insulating film 16. Since the length of the overlapping portion of the gate electrode 11 and the source/drain wiring 217 in the channel length direction is set to not larger than 2 μm and the film thickness of the protective insulating film 16 is set to 200 to 400 nm in the present embodiment, the parasitic capacitance can be sufficiently reduced.

Meanwhile, the same effects as those in the first embodiment can be achieved at the source-gate crossing portion 2.

As above, the TFT of the present embodiment is also capable of high-speed operation although it is not as fast as that of the first embodiment.

### Third Embodiment

The structure of the thin-film transistor of the present embodiment is the same as that of the thin-film transistor of the second embodiment, except that the oxide semiconductor layer is patterned.

As illustrated in FIG. 13, the insulating layer 13 has formed thereon a semiconductor film 314 which is patterned to overlap the gate electrode 11 and the gate wiring 12. The semiconductor film 314 is formed from an IGZO film containing indium (In), gallium (Ga), zinc (Zn), and oxygen (0). At the transistor portion 1, source/drain wirings 317 are formed in such a manner to partially overlap the protective insulating film 16.

Hereinafter, the production process of the present embodiment is described. Although almost all the steps are the same as those of the second embodiment, the protective insulating film is patterned and then the oxide semiconductor layer is continuously patterned.

First, the steps are performed up to the step of forming the resist 23 on the SiO₂ film 21 by patterning through the same steps as in the first embodiment to form the structure illustrated in FIG. 14.

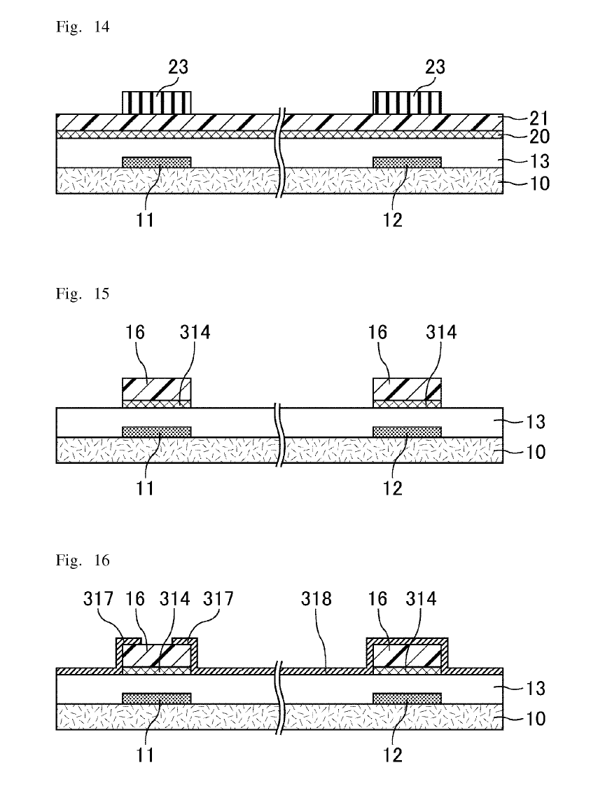

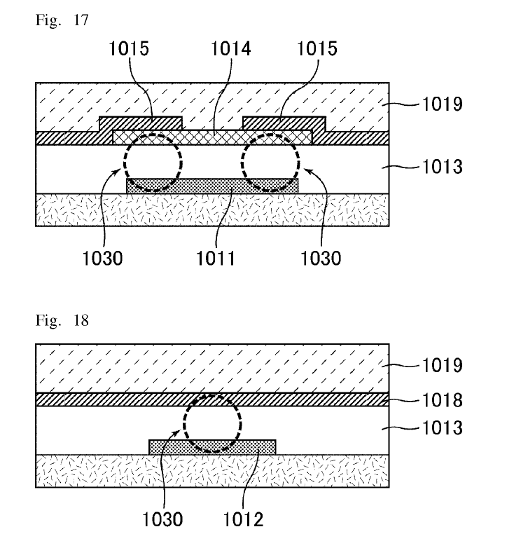

Next, the semiconductor layer 20 and the SiO₂ film 21 are continuously etched using the dry etching method, and thereafter the resist 23 is removed. Thereby, as illustrated in FIG. 15, the protective insulating film 16 and the semiconductor film 314 are formed.

Next, a Ti film and a Cu film are formed to the respective film thicknesses of 50 to 100 nm and 200 nm to 400 nm by sputtering. Then, the stacked films are patterned by photolithography, and the source/drain wirings 317 including a source wiring 318 are formed as illustrated in FIG. 16. These steps allow the source/drain wirings 317 to be in direct contact with the side faces of the semiconductor film 314.

As illustrated in FIG. 13, the passivation film 19 is formed by a CVD method in such a manner to cover all the components formed thus far.

The channel of the TFT is formed under the semiconductor film 314, i.e., on the gate electrode 11 side. Therefore, the source/drain wirings 317 are directly connected to the channel in the present embodiment. Hence, the TFT of the present embodiment can provide higher mobility than that of the second embodiment.

Meanwhile, the same effects as those in the second embodiment can be achieved at the source-gate crossing portion 2.

As above, the TFT of the present embodiment is also capable of high-speed operation although it is not as fast as that of the second embodiment.

The present application claims priority to Patent Application No. 2009-239716 filed in Japan on Oct. 16, 2009 under the Paris Convention and provisions of national law in a designated State, the entire contents of which are hereby incorporated by reference.

### EXPLANATION OF SYMBOLS

1: Transistor portion

2: Source-gate crossing portion

3: Display area

10: Glass substrate

11, 1011: Gate electrode

12, 1012: Gate wiring

13, 1013: Insulating film

14, 214, 314, 1014: Semiconductor film

15, 1015: Source/drain electrode

16: Protective insulating film

17, 217, 317: Source/drain wiring

18, 218, 318, 1018: Source wiring

19, 1019: Passivation film

20: Semiconductor layer

21: SiO₂ film

22: Resist layer

23: Resist

24: Conducting film

25: Drain wiring

26: Pixel electrode

1030: Parasitic capacitance

1. A bottom-gate thin-film transistor, comprising, on a substrate, in the order of:
a gate electrode;
a gate insulating film;
an oxide semiconductor film; and
a protective insulating film,
the protective insulating film having a planar shape that is completely or substantially the same as the planar shape of the gate electrode.

2. The thin-film transistor according to claim 1, further comprising a source/drain electrode connected to a channel formed in the oxide semiconductor film,
wherein the source/drain electrode and the oxide semiconductor film are formed from the same semiconductor layer, and
the source/drain electrode is formed by reducing a part of the semiconductor layer.

3. The thin-film transistor according to claim 1, further comprising a gate wiring connected to the gate electrode,
wherein the protective insulating film extends over the gate wiring, and
the protective insulating film has a planar shape that is completely or substantially the same as the planar shape of the gate wiring.

4. The thin-film transistor according to claim 1,
wherein the protective insulating film contains SiO₂.

5. The thin-film transistor according to claims 1,
wherein the gate insulating film contains SiO₂.

6. The thin-film transistor according to any claims 1,
wherein the oxide semiconductor film contains at least one element selected from the group consisting of indium, gallium, zinc, aluminum, and silicon.

7. A process for producing the thin-film transistor according to claim 1, comprising
exposing a resist layer formed on the insulating layer used to form the protective insulating film, from the substrate side.

8. A display device, comprising the thin-film transistor according to claim 1.

9. The display device according to claim 8,
wherein the source/drain electrode functions as a source electrode,
the thin-film transistor further comprises a gate wiring connected to the gate electrode and a source wiring connected to the source electrode,
the protective insulating film extends over the gate wiring, and
at a crossing portion of the gate wiring and the source wiring, at least one of the protective insulating film and the oxide semiconductor film has a planar shape that is completely or substantially the same as the planar shape of the gate wiring.
